(19) United States
(12) Patent Application Publication
(10) Pub. No.: US 2012/0092036 A1
(43) Pub. Date: Apr. 19, 2012

(54) UPRIGHT TEST APPARATUS FOR ELECTRONIC ASSEMBLIES

(76) Inventor: Wen-Hsien LO, Miaoli County (TW)

(21) Appl. No.: 13/271,649

(22) Filed: Oct. 12, 2011

(30) Foreign Application Priority Data
Oct. 15, 2010 (TW) 099135222

(51) Int. Cl. G01R 31/20

(52) U.S. Cl. 324/757.02

(57) ABSTRACT

An upright test apparatus for electronic assemblies includes a case assembly, first motherboard assemblies and a handler. The first motherboard assemblies are disposed in the case assembly. Each first motherboard assembly includes a motherboard, a first main connector, an adapter, a first sub-connector and a central processing unit (CPU). The motherboard is vertically disposed in the case assembly. The first main connector is disposed on the motherboard and electrically connected to the motherboard. The adapter is electrically connected to the first main connector and is substantially perpendicular to the motherboard. The first sub-connector is disposed on the adapter. The CPU is disposed on the motherboard and electrically connected to the motherboard. The handler inserts the electronic assemblies into the first sub-connectors in a vertical direction, respectively, tests the electronic assemblies and removes the electronic assemblies after the electronic assemblies are tested.

This application claims priority of No. 099135222 filed in Taiwan R.O.C. on Oct. 15, 2010 under 35 USC 119, the entire content of which is hereby incorporated by reference.

### BACKGROUND OF THE INVENTION

1. Field of the Invention

The invention relates in general to a test apparatus, and more particularly to an upright test apparatus for electronic assemblies.

2. Related Art

A conventional method for testing a memory module is usually performed in an artificial manner using a dedicated test apparatus. For example, the memory module may be inserted into a memory socket of a motherboard connected to a video card connected to a display, and then the motherboard is powered on for test. The tester watches the test results in an artificial manner, and then classifies the tested memory modules according to the test results.

Although the memory module can be inserted and removed through a robot arm, the motherboard must be placed horizontally so that the robot arm can insert the memory module into the memory socket on the motherboard. However, the motherboard occupies a relatively large horizontal area. If a lot of memory modules have to be tested, a lot of motherboards are needed and only can be placed horizontally. In this manner, a relatively large space is occupied, it is disadvantageous to the minimization of the test place, and the test cost is thus increased.

### SUMMARY OF THE INVENTION

It is therefore an object of the invention to provide an upright test apparatus for automatically testing electronic assemblies to save the test space and decrease the test cost.

To achieve the above-identified object, the invention provides an upright test apparatus including a case assembly, first motherboard assemblies and a handler. Each of the first motherboard assemblies is disposed in the case assembly and includes a motherboard, a first main connector, an adapter, a first sub-connector and a central processing unit (CPU). The motherboard is vertically disposed in the case assembly. The first main connector is disposed in the motherboard and electrically connected to the motherboard. The adapter is electrically connected to the first main connector and substantially perpendicular to the motherboard. The first sub-connector is disposed on the adapter. The CPU is disposed on the motherboard and electrically connected to the motherboard. The handler inserts a plurality of electronic assemblies into the first sub-connectors in a vertical direction, respectively, tests the electronic assemblies and removes the electronic assemblies after the electronic assemblies are tested.

According to the above-mentioned upright test apparatus, the larger test capacity can be obtained in the limited space, and the test cost can be effectively reduced.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is an overall schematic illustration showing an upright test apparatus according to a first embodiment of the invention.

FIG. 2 is a partial schematic illustration showing the upright test apparatus of FIG. 1.

FIG. 3 is a partial pictorial view showing the upright test apparatus of FIG. 1.

FIG. 4 is a partial schematic illustration showing an upright test apparatus according to a second embodiment of the invention.

FIG. 5 is a partial schematic illustration showing an upright test apparatus according to a third embodiment of the invention.

FIGS. 6 and 7 are partial schematic illustrations showing the upright test apparatus according to the third embodiment of the invention.

FIG. 8 shows connection relationships between a handler, a power supply and a motherboard according to the invention.

FIG. 9 is a schematic illustration showing a first motherboard assembly according to a fourth embodiment of the invention.

### DETAILED DESCRIPTION OF THE INVENTION

The present invention will be apparent from the following detailed description, which proceeds with reference to the accompanying drawings, wherein the same references relate to the same elements.

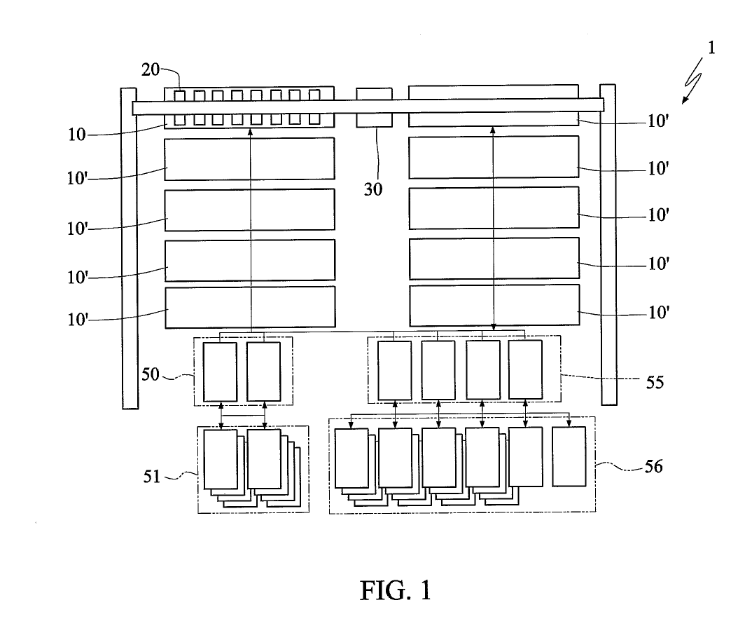

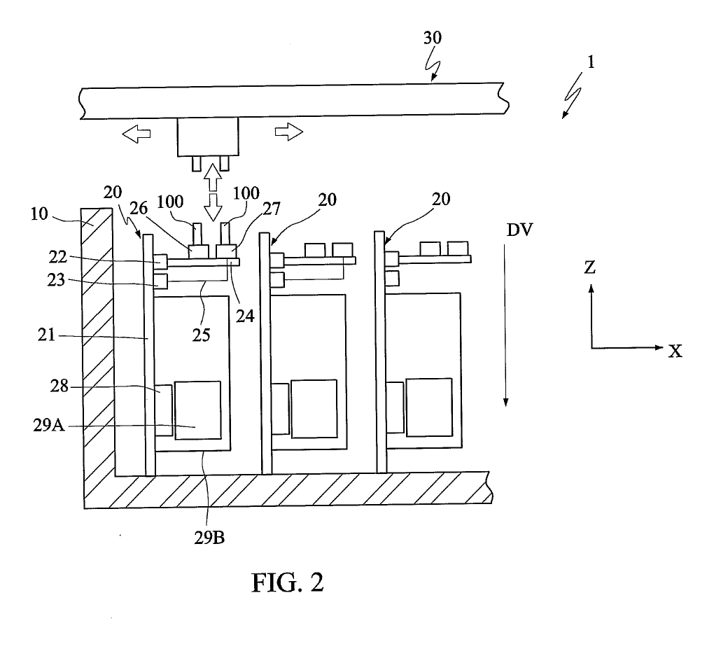

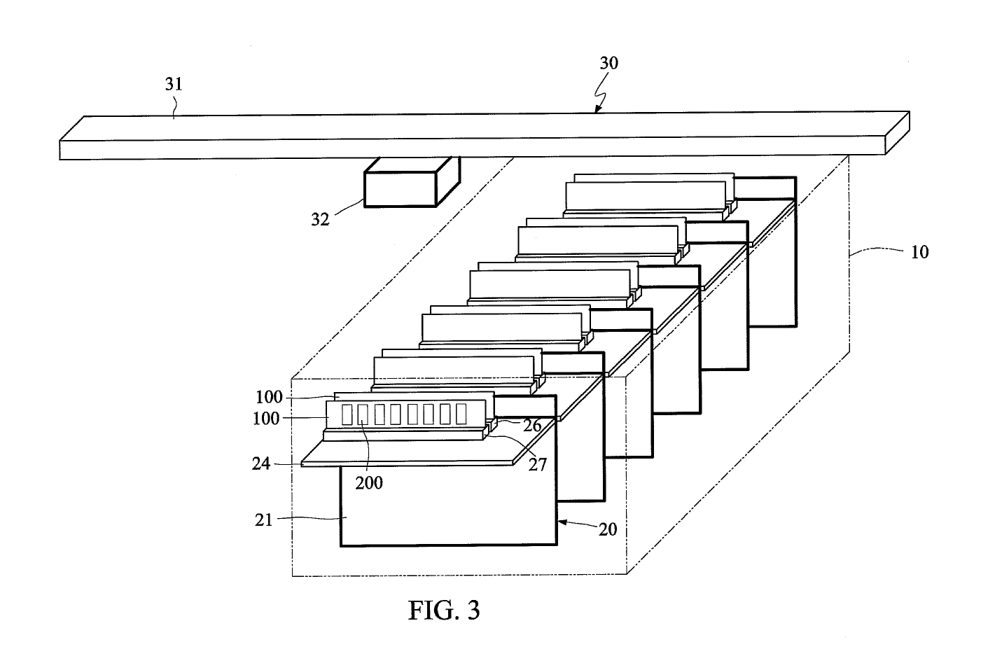

FIG. 1 is an overall schematic illustration showing an upright test apparatus 1 according to a first embodiment of the invention. FIG. 2 is a partial schematic illustration showing the upright test apparatus 1 of FIG. 1. FIG. 3 is a partial pictorial view showing the upright test apparatus 1 of FIG. 1.

Referring to FIGS. 1 to 3, the upright test apparatus 1 of this embodiment includes a case assembly 10, a plurality of first motherboard assemblies 20 and a handler 30. Of course, the upright test apparatus 1 may further include a plurality of additional case assemblies 10′. The functions of the additional case assemblies 10′ are similar to those of the case assembly 10 so that the test capability can be increased. In the following, the internal structure of only one single case assembly 10 is illustrated.

Each of the first motherboard assemblies 20 is disposed in the case assembly 10 and includes a motherboard 21, a first main connector/socket 22, an adapter 24, a first sub-connector/sub-socket 26 and a central processing unit (CPU) 28. The motherboards 21 may be selected from various brands of commercial available motherboards and are vertically disposed in the case assembly 10. Consequently, specific motherboards may be purchased according to the customer's requirements, and the memory modules may be tested on the specific motherboards. Of course, a dedicated motherboard may also be used for the test. The first main connector 22 is disposed on the motherboard 21 and electrically connected to the motherboard 21. The adapter 24 is electrically connected to the first main connector 22 and substantially perpendicular to the motherboard 21. The adapter 24 may be a single adapter board or may include an adapter board, mounted on the case assembly 10 or the first motherboard assembly 20, and a cable electrically connecting the adapter board to the first main connector 22. The first sub-connector 26 is disposed on the adapter 24. The CPU 28 is disposed on the motherboard 21 and electrically connected to the motherboard 21.

The handler 30 inserts a plurality of electronic assemblies 100 into the first sub-connectors 26 in a vertical direction DV, respectively, tests the electronic assemblies 100 and removes the electronic assemblies 100 after the electronic assemblies 100 have been tested. The electronic assembly 100 is, for example, a memory module, such as a DIMM memory module, on which a plurality of integrated circuits (ICs) 200 is mounted. The handler 30 includes a suspension frame 31 and a robot arm 32, and may further include associated modules for performing data processing and controlling the classifying procedures. The robot arm 32 may move along the suspension frame 31 (in the X-axis direction), the suspension frame 31 may also be moved in the Y-axis direction, and the robot arm 32 of the handler 30 may take and move one or more than one electronic assembly 100 at a time in the Z-axis direction. The electronic assembly 100 includes, without limitation to, a memory module, a hard drive, an optical disk drive, an electronic card or the like.

In addition, the test apparatus 1 may further include a temporary storage area 50, a storage area 51, a coarse classification area 55 and a fine classification area 56. The handler 30 takes the electronic assemblies 100 from the temporary storage area 50 and then inserts the electronic assemblies 100 into the first sub-connectors 26. The handler 30 moves the tested electronic assemblies 100 to the coarse classification area 55 according to a plurality of test results (e.g., normal or abnormal results), respectively. The electronic assemblies 100, which have not been tested, can be placed in the storage area 51, and then placed in the fine classification area 56 after being tested.

It is to be noted that another handler (not shown) may be provided to move the electronic assemblies 100 from the storage area 51 to the temporary storage area 50, or from the coarse classification area 55 to the fine classification area 56. Of course, the handler 30 may further perform the above-mentioned operations.

In addition, each first motherboard assembly 20 may further include a second main connector/socket 23, a second sub-connector/sub-socket 27, a connection wire 25, a heat dissipating fan 29A and a video card 29B. The second main connector 23 is disposed on the motherboard 21 and electrically connected to the motherboard 21. The second sub-connector 27, disposed in the adapter 24, receives one of the inserted electronic assemblies 100 for the test. The connection wire 25 is electrically connected to the second sub-connector 27 and the adapter 24. The heat dissipating fan 29A is disposed on the CPU 28. The video card 29B is disposed on and electrically connected to the motherboard 21. The user may connect a display (not shown) to the video card 29B so that the tester can watch the test condition and result. However, the video card 29B is not the essential element because the data in all the test processes can be monitored and processed by the handler 30.

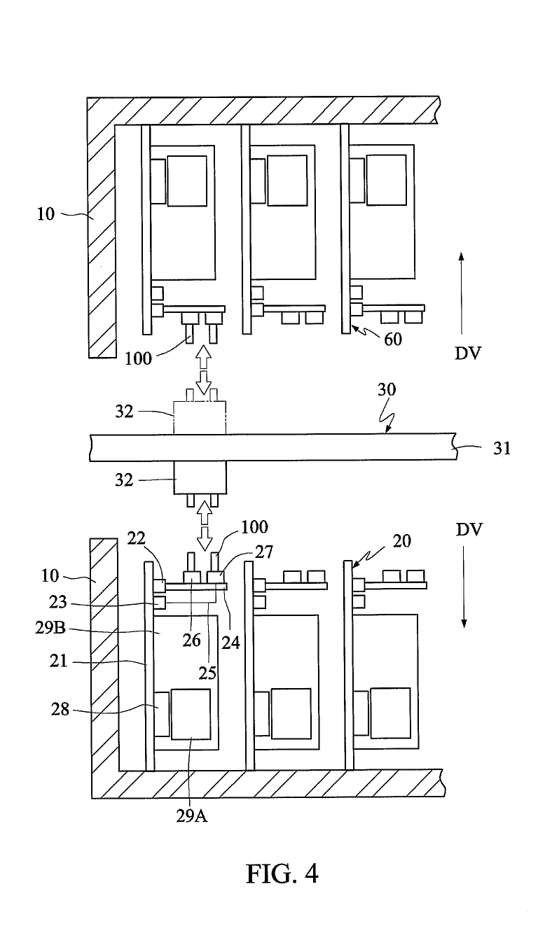

FIG. 4 is a partial schematic illustration showing an upright test apparatus according to a second embodiment of the invention. As shown in FIG. 4, the test apparatus of this embodiment is similar to the first embodiment except that the test apparatus of the second embodiment further includes a plurality of second motherboard assemblies 60 disposed in the case assembly 10 and stacked above the first motherboard assemblies 20. The structures and functions of the second motherboard assemblies 60 are the same as the structures and functions of the first motherboard assemblies 20. In this embodiment, the handler 30 can travel between the second motherboard assemblies 60 and the first motherboard assemblies 20, and downwardly inserts one portion of the electronic assemblies 100 into the first motherboard assemblies 20 and upwardly inserts the other portion of electronic assemblies 100 into the second motherboard assemblies 60 as long as the robot arm 32 can flip about the suspension frame 31. For the upper case assembly 10, the vertical direction DV, in which the handler 30 inserts the electronic assembly 100 into the first sub-connector 26, is the same as the direction of gravity of the electronic assembly 100. For the lower case assembly 10, the vertical direction DV, in which the handler 30 inserts the electronic assembly 100 into the first sub-connector 26, is opposite to the direction of gravity of the electronic assembly 100. The upper and lower case assemblies 10 may be present exclusively or concurrently.

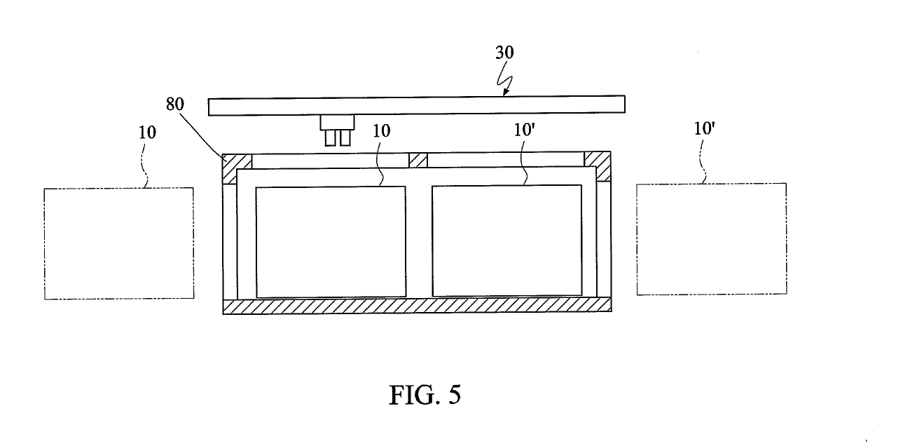

FIG. 5 is a partial schematic illustration showing an upright test apparatus according to a third embodiment of the invention. As shown in FIG. 5, this embodiment is similar to the first embodiment except that the case assembly 10 and the additional case assemblies 10′ are disposed in a machine casing 80, and the case assembly 10 and the additional case assemblies 10′ may be moved out of the machine casing 80 for maintenance.

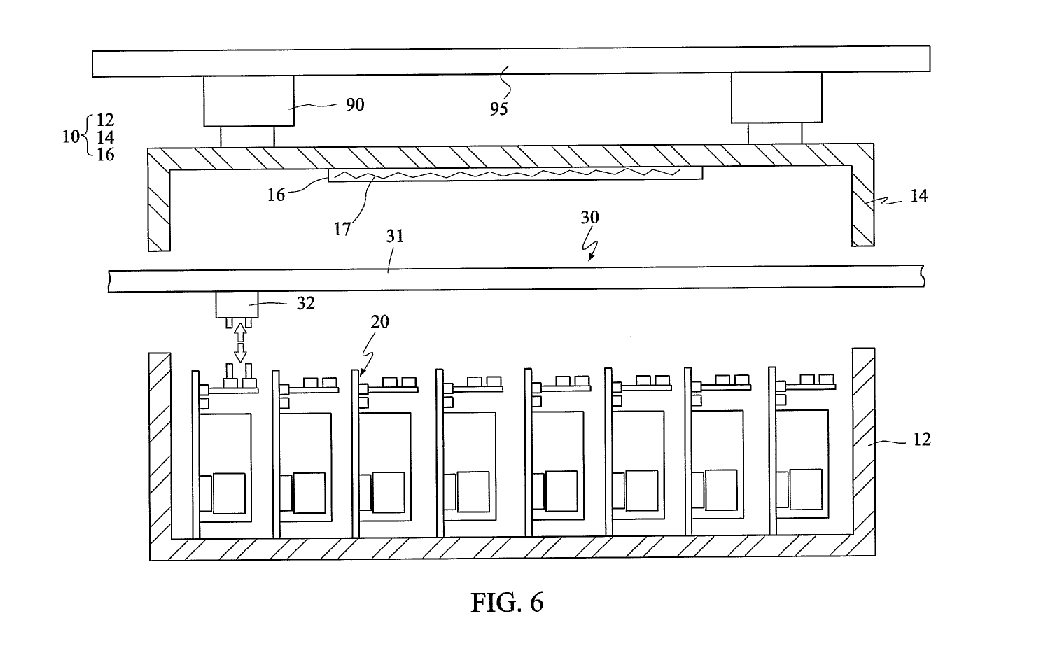

FIGS. 6 and 7 are partial schematic illustrations showing the upright test apparatus according to the third embodiment of the invention. Referring to FIGS. 6 and 7, the case assembly 10 of the test apparatus of this embodiment includes a base 12, an upper cover 14 and a temperature control module 16. The first motherboard assemblies 20 are mounted in the base 12. The upper cover 14 may be moved to cover the base 12 and the first motherboard assemblies 20. The temperature control module 16, disposed in a chamber 18 formed by the upper cover 14 and the base 12, controls the temperature of the chamber 18 or the temperature of the gas in the chamber 18. In one example, the temperature control module 16 includes a heater 17. In another example, the temperature control module may include a gas supply for supplying a gas or gases to the chamber 18 to control the temperature. After the handler 30 finishes inserting the electronic assemblies 100, the handler 30 moves away, and then an oil cylinder 90 of an oil-cylinder suspension frame 95 pushes the upper cover 14 downward to contact the base 12 in a closed manner, so that the tests at some specific temperatures may be performed according to the customer's requirements.

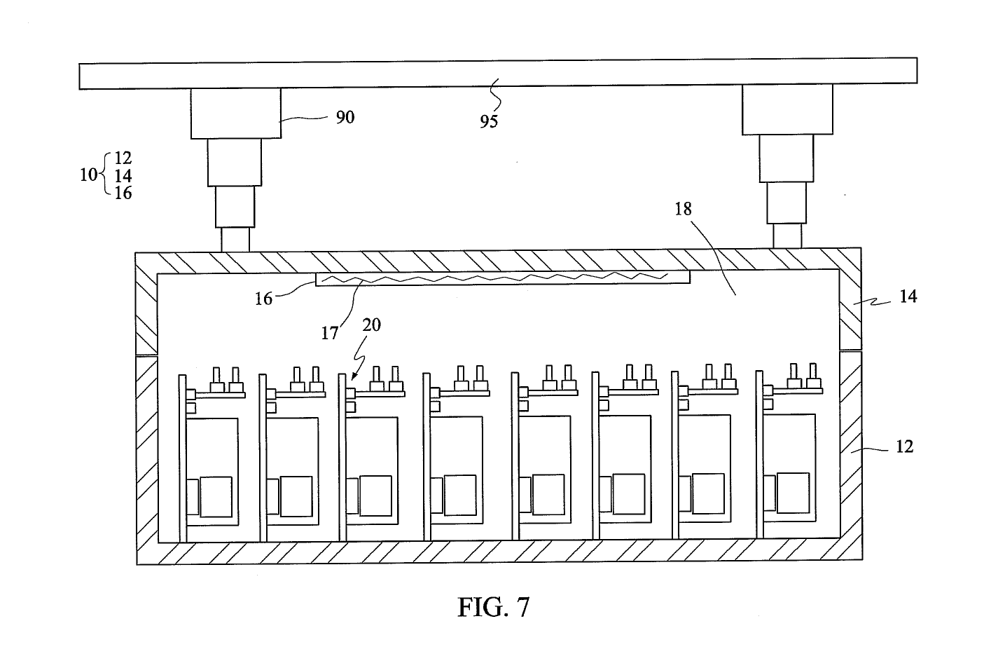

FIG. 8 shows connection relationships between the handler, a power supply and a motherboard according to the invention. Referring to FIG. 8, the test apparatus of the invention may further include a power supply 40 electrically connected to the handler 30. The handler 30 is electrically connected to the motherboard 21, and the handler 30 inserts the electronic assembly 100 into the first sub-connector 26 and then turns on the power supply 40 and the motherboard 21 to perform the test. After the test is finished, the handler 30 turns off the power supply 40 and the motherboard 21 and then removes the electronic assemblies 100. Therefore, all the test processes can be performed or monitored by the handler 30, and the number of the required testers can be significantly decreased.

The test processes will be described in the following. First, the handler 30 takes the electronic assembly (or assemblies) 100 from the temporary storage area 50 and inserts the electronic assembly (or assemblies) 100 into the first sub-connector 26 and/or the second sub-connector 27, then turns on the motherboard 21, reads the signal of the motherboard 21 and determines whether the signal is normal. If the signal is abnormal, the motherboard 21 is turned off or shut down, and the electronic assembly 100 is replaced with a new one for test. If the signal of the motherboard 21 is normal, the above-mentioned procedures are repeated to insert the electronic assemblies 100 into the other motherboards 21 in the case assembly 10. The power-on test of the motherboard usually needs a long period of time, such as 1,500 to 3,000 seconds or longer. So, the handler 30 can continue to use the motherboards 21 in the other additional case assemblies 10′ to perform the tests of the other electronic assemblies 100 by repeating the above-mentioned steps. After all the case assemblies 10′ have been occupied by the electronic assemblies 100, it is determined whether the test times are due. If not, the waiting is continued. If the test time is due, the signal of each motherboard 21 is read to judge whether the test result of the electronic assembly 100 is normal, and the electronic assembly 100 is removed and transported to the coarse classification area 55 according to the test result. In addition, another handler can be provided to transport the electronic assembly 100 from the coarse classification area 55 to the fine classification area 56.

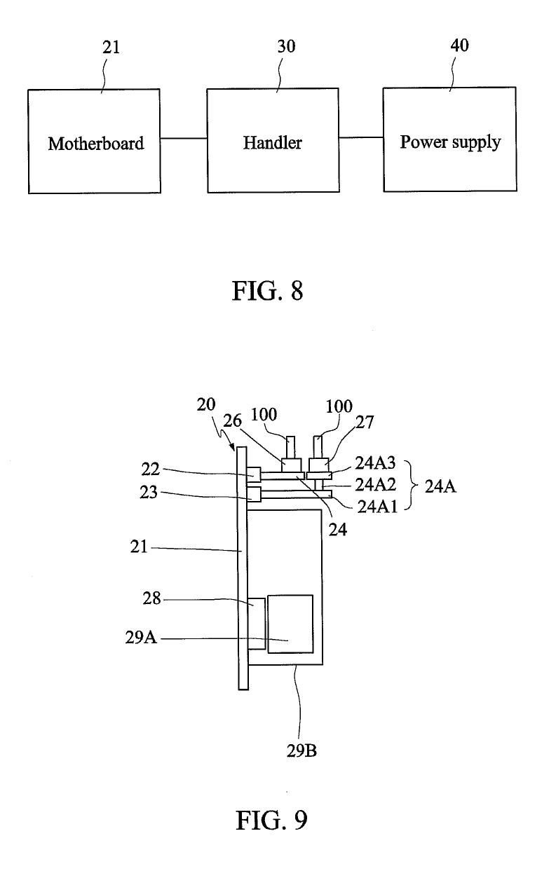

FIG. 9 is a schematic illustration showing a first motherboard assembly 20′ according to a fourth embodiment of the invention. As shown in FIG. 9, the first motherboard assembly 20′ of this embodiment is similar to the first embodiment except that the first motherboard assembly 20′ further includes a second main connector 23, a second adapter 24A and a second sub-connector 27. The second main connector 23 is disposed on the motherboard 21 and electrically connected to the motherboard 21. The second adapter 24A is electrically connected to the second main connector 23 and substantially perpendicular to the motherboard 21. The second sub-connector 27, disposed on the second adapter 24A, receives one of the inserted electronic assemblies 100 for the test. The second sub-connector 27 and the first sub-connector 26 are disposed on the same horizontal plane or surface, such that the handler 30 can be positioned more conveniently. The second adapter 24A may have the lifted structure, as shown in the drawing. That is, the lifted structure includes a first horizontal extension plate 24A1, a second horizontal extension plate 24A3 and a vertical extension plate 24A2. The vertical extension plate 24A2 is connected to the first horizontal extension plate 24A1 and the second horizontal extension plate 24A3, while the second sub-connector 27 is disposed on the second horizontal extension plate 24A3. It is to be noted that the first horizontal extension plate 24A1, the second horizontal extension plate 24A3 and the vertical extension plate 24A2 may be separately formed or integrally formed. In addition, this first motherboard assembly 20′ may be applied to all the above-mentioned embodiments for the tests.

According to the upright test apparatus, the adapter 24 enables the handler 30 to insert the electronic assembly 100 into the first sub-connector 26/second sub-connector 27 in the vertical direction. The horizontally extended dimension of the adapter 24 is very small, and the gap between the upright motherboards 21 can be effectively reduced. So, it is possible to obtain the larger test capacity in the limited chamber, and to effectively decrease the test cost.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. An upright test apparatus, comprising:
a case assembly;
a plurality of first motherboard assemblies, each of which is disposed in the case assembly and comprises:
a motherboard vertically disposed in the case assembly;
a first main connector, which is disposed in the motherboard and electrically connected to the motherboard;
an adapter, which is electrically connected to the first main connector and substantially perpendicular to the motherboard;
a first sub-connector disposed on the adapter; and
a central processing unit (CPU), which is disposed on the motherboard and electrically connected to the motherboard; and
a handler for inserting a plurality of electronic assemblies into the first sub-connectors in a vertical direction, respectively, testing the electronic assemblies and removing the electronic assemblies after the electronic assemblies are tested.

2. The test apparatus according to claim 1, further comprising:
a power supply electrically connected to the handler, wherein the handler electrically connected to the motherboard inserts the electronic assemblies into the first sub-connectors and then turns on the power supply and the motherboard to test the electronic assemblies, turns off the power supply and the motherboard after the electronic assemblies are tested, and then removes the electronic assemblies.

3. The test apparatus according to claim 1, further comprising:
a coarse classification area, wherein the handler moves the electronic assemblies, which have been tested, to the coarse classification area according to a plurality of test results.

4. The test apparatus according to claim 1, further comprising:
a temporary storage area, wherein the handler takes the electronic assemblies from the temporary storage area and then inserts the electronic assemblies into the first sub-connector, respectively.

5. The test apparatus according to claim 1, wherein each of the first motherboard assemblies further comprises:
a second main connector disposed on the motherboard and electrically connected to the motherboard;
a second sub-connector, disposed on the adapter, for receiving one of the electronic assemblies to be tested; and
a connection wire electrically connected to the second sub-connector and the adapter.

6. The test apparatus according to claim 1, further comprising:
a plurality of second motherboard assemblies disposed in the case assembly and stacked above the first motherboard assemblies, wherein structures and functions of the second motherboard assemblies are the same as structures and functions of the first motherboard assemblies, and the handler moves between the second motherboard assemblies and the first motherboard assemblies, downwardly inserts one portion of the electronic assemblies into the first motherboard assemblies and upwardly inserts the other portion of the electronic assemblies into the second motherboard assemblies.

7. The test apparatus according to claim 1, wherein the case assembly comprises:
a base, wherein the first motherboard assemblies are mounted in the base;
an upper cover, which is movable to cover the base and the first motherboard assemblies; and
a temperature control module, disposed in a chamber formed by the upper cover and the base, for controlling a temperature of the chamber.

8. The test apparatus according to claim 7, wherein the temperature control module comprises a heater.

9. The test apparatus according to claim 1, wherein the handler takes multiple electronic assemblies of the electronic assemblies at a time.

10. The test apparatus according to claim 1, wherein each of the first motherboard assemblies further comprises:
a heat dissipating fan disposed on the CPU; and
a video card disposed on the motherboard.

11. The test apparatus according to claim 1, further comprising a plurality of additional case assemblies, wherein the case assembly and the additional case assemblies are disposed in a machine casing, and the case assembly and the additional case assemblies may be moved out of the machine casing for maintenance.

12. The test apparatus according to claim 1, wherein the vertical direction is the same as a direction of gravity of the electronic assembly.

13. The test apparatus according to claim 1, wherein the vertical direction is opposite to a direction of gravity of the electronic assembly.

14. The test apparatus according to claim 1, wherein each of the first motherboard assemblies further comprises:
a second main connector disposed on the motherboard and electrically connected to the motherboard;
a second adapter, which is electrically connected to the second main connector and substantially perpendicular to the motherboard; and
a second sub-connector, disposed on the second adapter, for receiving one of the inserted electronic assemblies, wherein the second sub-connector and the first sub-connector are disposed on the same horizontal plane.
